(19) United States
(12) Patent Application Publication
(10) Pub. No.: US 2014/0177183 A1
(43) Pub. Date: Jun. 26, 2014

(54) SUPPORTING APPARATUS AND DISPLAY DEVICE HAVING THE SUPPORTING APPARATUS

(71) Applicant: HON HAI PRECISION INDUSTRY CO., LTD., New Taipei (TW)

(72) Inventor: CHENG-YI LAI, New Taipei (TW)

(73) Assignee: HON HAI PRECISION INDUSTRY CO., LTD., New Taipei (TW)

(21) Appl. No.: 14/105,403

(22) Filed: Dec. 13, 2013

(30) Foreign Application Priority Data
Dec. 21, 2012 (TW) 101224792

(51) Int. Cl. F16M 13/02; H05K 7/14; H02H 7/085

(52) U.S. Cl. CPC F16M 13/022; H02H 7/0851; H05K 7/1417
USPC 361/749; 318/468; 248/205.1

(57) ABSTRACT

A supporting apparatus for support an object includes a base, a rotation shaft, and a holding structure. The base includes a first magnet. The rotation shaft is located on the base. The holding structure is rotatably connected to the base via the rotation shaft. The holding structure includes a second magnet corresponding to the first magnet. The first magnet and the second magnet are spaced from each other a predetermined distance.

### BACKGROUND

1. Technical Field

The disclosure relates to a display device capable of supporting a camera using a supporting apparatus.

2. Description of Related Art

Some display devices, such as televisions and computers, have a supporting apparatus to support a camera to capture images or videos. However, supporting apparatuses used in these display devices can only support a small or light-weight camera. Therefore, there is room for improvement in the art.

### BRIEF DESCRIPTION OF THE DRAWINGS

The accompanying drawings are included to provide a further understanding of the disclosure, and are incorporated in and constitute a part of this application. The drawings illustrate embodiments of the disclosure and, together with the description, serve to explain the principles of the disclosure.

FIG. 1 is a schematic view of an embodiment of a supporting apparatus.

FIG. 2 is an exploded perspective view of the supporting apparatus of FIG. 1.

FIG. 3 illustrates a schematic view of a holding structure of the supporting apparatus of FIG. 1.

FIG. 4 is a cross-sectional view of the supporting apparatus taken along line IV-IV of FIG. 1.

FIG. 5 shows the supporting apparatus of FIG. 1 installed on a display device to support a camera.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

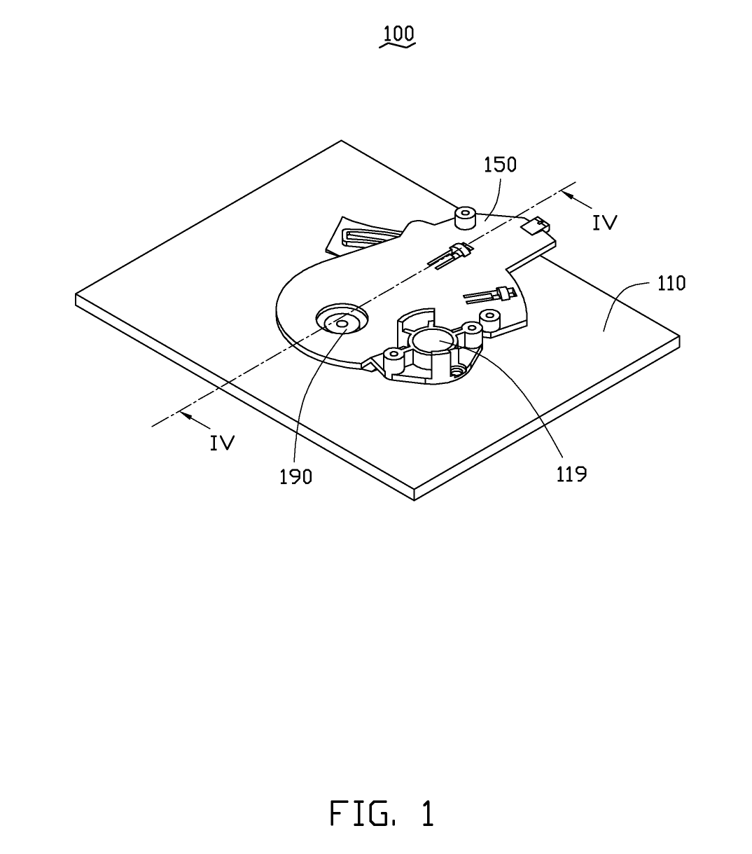

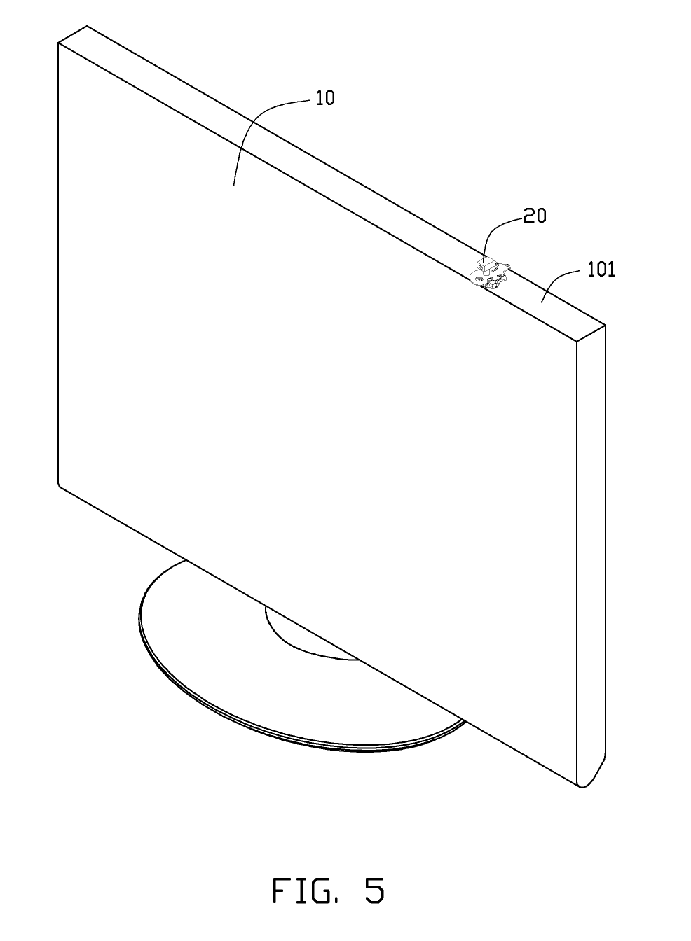

FIG. 1 shows a supporting apparatus 100. In one embodiment, the supporting apparatus 100 is a camera supporter used in a display device 10 (as shown in FIG. 5) to support a camera of the display device 10. The supporting apparatus 100 can be an independent structure separate from the display device 10. In another embodiment, the supporting apparatus 100 can be integrated with the display device 10. The supporting apparatus 100 includes a base 110, a holding structure 150, and a rotation shaft 190. The holding structure 150 is rotatably connected to the base 110 via the rotation shaft 190. In the illustrated embodiment, the base 110 and the holding structure 150 are made of plastic materials.

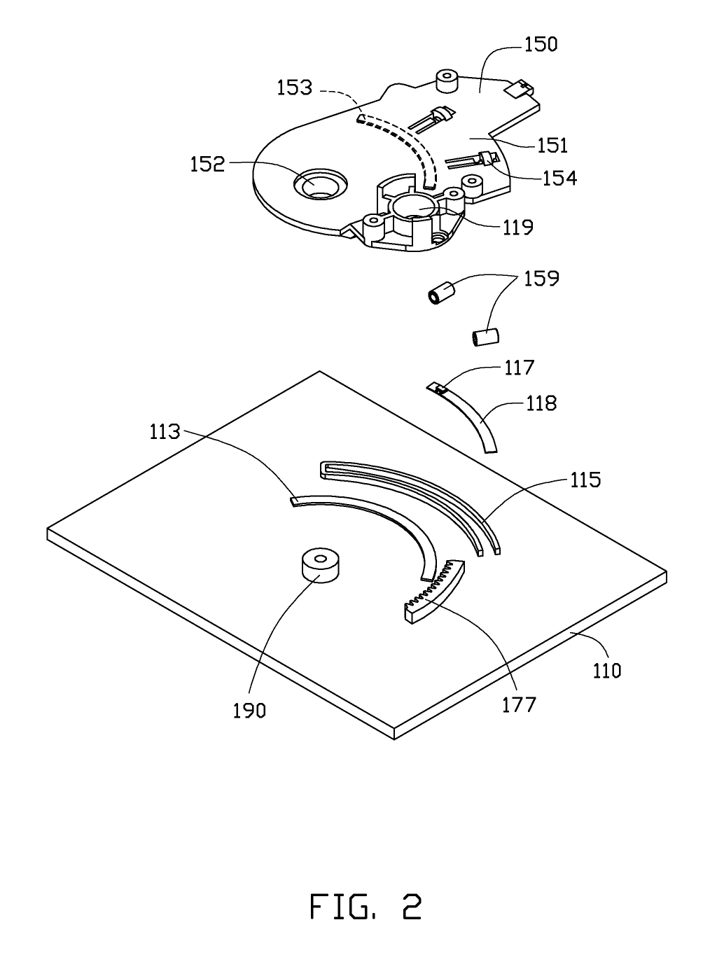

Referring to FIG. 2, the rotation shaft 190 protrudes from the base 110. The base 110 further includes a first magnet 113, a guiding rail 115, and a toothed bar 177. The first magnet 113, the guiding rail 115, and the toothed bar 177 are all arcuate. The toothed bar 177 couples with an edge of the holding structure 150 when the holding structure 150 is rotated relative to the base 110. The first magnet 113 and the guiding rail 115 are located on a side of the base 110 facing the holding structure 150. In one embodiment, the first magnet 113 is nearer to the rotation shaft 190 than the guiding rail 115. The guiding rail 115 protrudes from a surface of the base 110 facing the holding structure 150. The guiding rail 115 is two substantially parallel arcuate protrusion bars.

The supporting apparatus 100 further includes a flexible printed circuit (FPC) board 118, a sensor 117 located on the FPC board 118, and a driver 119 configured to drive the holding structure 150 to rotate relative to the base 110 along the guiding rail 115. The sensor 117 is located on a surface of the base 110 facing the holding structure 150. The sensor 117 and the FPC board 118 are received in a space between the two arcuate protrusion bars of the guiding rail 115. In one embodiment, the guiding rail 115 is made of plastic materials, the driver 119 is a servo motor, and the sensor 117 is a Hall sensor configured to detect a rotation distance of the holding structure 150 relative to the base 110.

The driver 119 is electrically connected to the sensor 117 via the FPC board 118. The driver 119 stops rotating the holding structure 150 when a command is sent from the sensor 117. Thus, the holding structure 150 is prevented from rotating out of the guiding rail 115.

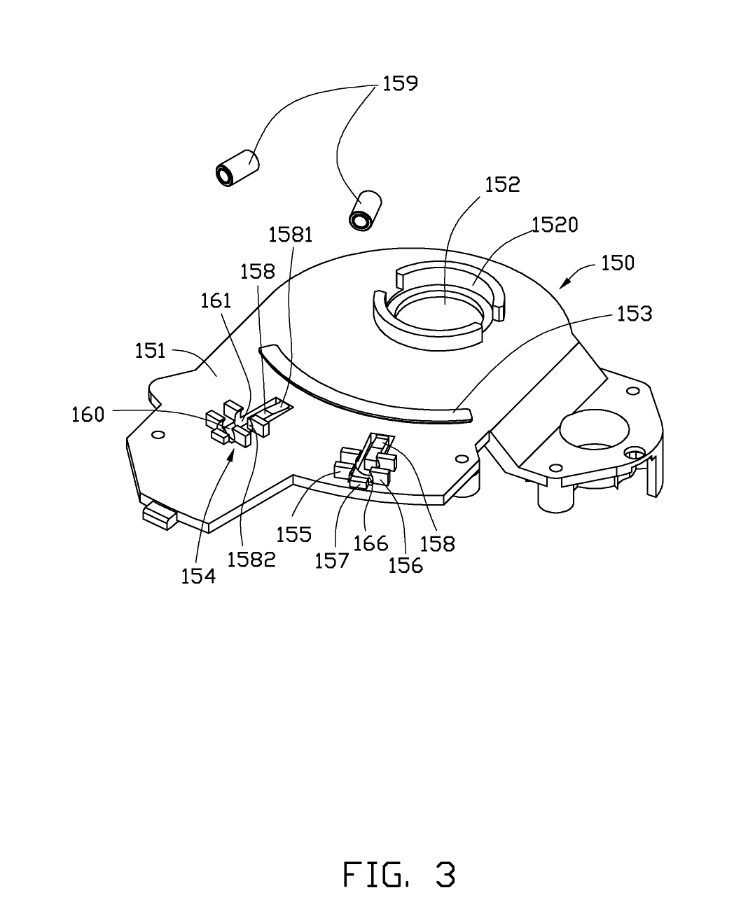

Referring to FIG. 3, the holding structure 150 includes a main body 151, a through hole 152 defined through the main body 151, a second magnet 153, one or more magnetic members 159, and one or more fixing members 154. The through hole 152 receives the rotation shaft 190. The holding structure 150 further includes a limiting wall 1520. The limiting wall 1520 extends along an edge of the through hole 152 to space the holding structure 150 from the base 110 a certain distance. The second magnet 153 is located on a side of the main body 151 facing the first magnet 113 of the base 110. The first magnet 113 and the second magnet 153 are spaced from each other the certain distance and are arranged exclusive from each other. In one embodiment, a distance between the first magnet 113 and the second magnet 153 is about 0.5 millimeters (mm), and a shape of the second magnet 153 is substantially similar to a shape of the first magnet 113.

In the illustrated embodiment, there are two magnetic members 159, and the magnetic members are substantially cylindrical. The magnetic members 159 can be, but are not limited to, standard magnetic cylindrical rollers, magnetic cylinder rollers sleeved with self-lubricating plastics, or steel rollers sleeved with magnetic annular rubber.

In the illustrated embodiment, there are two fixing members 154. Each fixing member 154 accommodates one magnetic member 159 therein. Each fixing member 154 includes two substantially parallel first sidewalls 155, two substantially parallel second sidewalls 156, a resisting wall 157, and an elastic arm 158. The first sidewalls 155 are arranged opposite to the second sidewalls 156. The resisting wall 157 is arranged between the first sidewalls 155 and the second sidewalls 156. The first sidewalls 155, the second sidewalls 156, and the resisting wall 157 cooperatively form a receiving space 160 having an opening 161. The receiving space 160 receives the magnetic member 159. The elastic arm 158 includes a connecting end portion 1581 and a free end portion 1582.

The connecting end portion 1581 is connected to the main body 151. The free end portion 1582 extends into the receiving space 160 through the opening 161. An arcuate bottom wall 166 is formed at a bottom of the receiving space 160 to conform to the shape of the magnetic member 159. In addition, edge surfaces of the first sidewalls 155 and the second sidewalls 156 contacting the magnetic member 159 are arcuate to conform to the shape of the magnetic member 159.

The supporting apparatus 100 can support a bigger and heavier camera because of the force between the first magnet 113 and the second magnet 153.

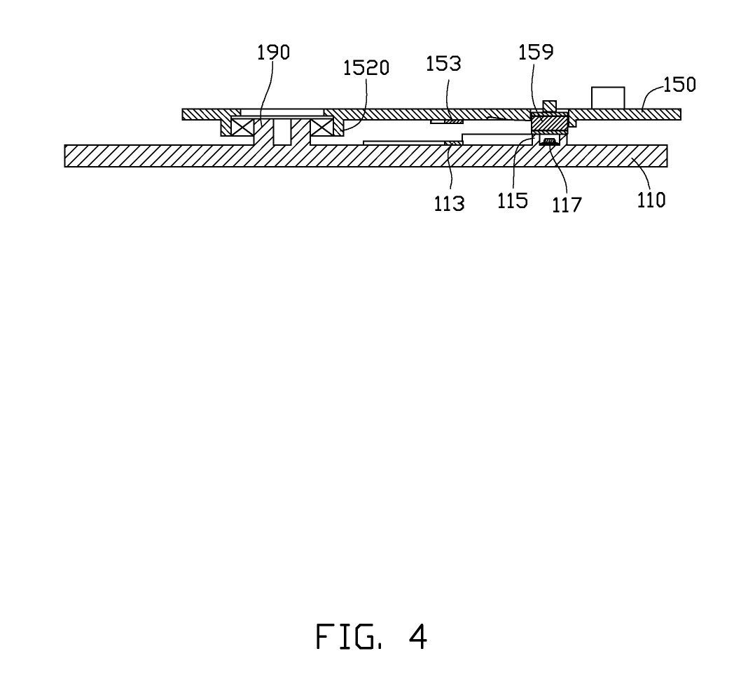

Referring to FIG. 4, in an original state, the sensor 117 is located at a central position between the two magnetic members 159. When the holding structure 150 is driven to rotate relative to the base 110, the two magnetic members 159 roll along the guiding rail 115. When one of the magnetic members 159 rolls to a position corresponding to the sensor 117, the sensor 117 senses the magnetic member 159 and generates the command to control the driver 119 to stop rotating the holding structure 150. Thus, the holding structure 150 is limited to rotate within a predetermined rotational range, which prevents the supporting apparatus 100 from being damaged. When the driver 119 is restarted, the holding structure 150 is rotated to the original state.

Referring to FIG. 5, the supporting apparatus 100 is used to support a camera 20 and is installed on the display device 10. In one embodiment, the base 100 is a portion of a shell 101 of the display device 10. The camera 20 is arranged on the holding structure 150.

In other embodiments, the sensor 117 can be a light sensor or a pressure sensor. When the sensor 117 is the light sensor, the light sensor generates the command when the light sensor is shielded by the holding structure 150. When the sensor 117 is the pressure sensor, the pressure sensor generates the command when the pressure sensor is pressed by the holding structure 150.

Although numerous characteristics and advantages of the present embodiments have been set out in the foregoing description, together with details of the structures and functions of the embodiments, the disclosure is illustrative only; and changes may be made in detail, especially in the matters of shape, size and arrangement of parts within the principles of the disclosure to the full extent indicated by the broad general meaning of the terms in which the appended claims are expressed.

What is claimed is:

1. A supporting apparatus, comprising:
a base comprising a first magnet;
a rotation shaft protruding from the base; and
a holding structure rotatably connected to the base via the rotation shaft, wherein the holding structure comprises a second magnet corresponding to the first magnet, and the first magnet and the second magnet are spaced from each other a predetermined distance and are arranged exclusive from each other.

2. The supporting apparatus according to claim 1, further comprising a driver, a flexible printed circuit (FPC) board, and a sensor located on the FPC board, wherein the driver is electrically connected to the sensor via the FPC board and is configured to drive the holding structure to rotate relative to the base.

3. The supporting apparatus according to claim 2, wherein the FPC board is located on the base, the holding structure further comprises one or more magnetic members, and the sensor is configured to sense the one or more magnetic members; when one of the one or more magnetic members is sensed by the sensor, the sensor generates a command to control the driver to stop rotating the holding structure.

4. The supporting apparatus according to claim 3, wherein the sensor is a Hall sensor generating the command when one of the one or more magnetic members is moved to a position corresponding to the Hall sensor.

5. The supporting apparatus according to claim 2, wherein the base further comprises a guiding rail; when the holding structure is rotated relative to the base, the one or more magnetic members move along the guiding rail.

6. The supporting apparatus according to claim 5, wherein the guiding rail is two substantially parallel arcuate protrusion bars protruding from a surface of the base facing the holding structure, and both the sensor and the FPC board are received in a space between the two arcuate protrusion bars.

7. The supporting apparatus according to claim 3, wherein the holding structure further comprises a main body, a through hole defined through the main body, and one or more fixing members configured to accommodate the one or more magnetic members; each fixing member comprises two substantially parallel first sidewalls, two substantially parallel second sidewalls, a resisting wall, and an elastic arm; the first sidewalls are arranged opposite to the second sidewalls, the resisting wall is arranged between the first sidewalls and the second sidewalls; the first sidewalls, the second sidewalls, and the resisting wall cooperatively form a receiving space having an opening to receive a magnetic member.

8. The supporting apparatus according to claim 7, wherein the elastic arm comprises a connecting end portion and a free end portion, the connecting end portion is connected to the main body, and the free end portion extends into the receiving space through the opening.

9. The supporting apparatus according to claim 8, wherein each of the one or more magnetic members is substantially cylindrical, and each fixing member further comprises an arcuate bottom wall formed at a bottom of the receiving space to conform to a shape of the magnetic member.

10. A display device, comprising a shell, a camera, and a supporting apparatus fixed on the shell and configured to support the camera, the supporting apparatus comprising:
a base comprising a first magnet;
a rotation shaft fixed on the base; and
a holding structure rotatably fixed on the base via the rotation shaft, wherein the holding structure comprises a second magnet corresponding to the first magnet, and the first magnet and the second magnet are spaced from each other a predetermined distance and are arranged exclusive from each other.

11. The display device according to claim 10, wherein the supporting apparatus further comprises a driver, a flexible printed circuit (FPC) board, and a sensor located on the FPC board, wherein the driver is electrically connected to the sensor via the FPC board and is configured to drive the holding structure to rotate relative to the base.

12. The display device according to claim 11, wherein the FPC board is located on the base, the holding structure further comprises one or more magnetic members, and the sensor is configured to sense the one or more magnetic members; when one of the one or more magnetic members is sensed by the sensor, the sensor generates a command to control the driver to stop rotating the holding structure.

13. The display device according to claim 12, wherein the sensor is a Hall sensor generating the command when one of the one or more magnetic members is moved to a position corresponding to the Hall sensor.

14. The display device according to claim 11, wherein the base further comprises a guiding rail; when the holding structure is rotated relative to the base, the one or more magnetic members move along the guiding rail.

15. The display device according to claim 14, wherein the guiding rail is two substantially parallel arcuate protrusion bars protruding from a surface of the base facing the holding structure, and both the sensor and the FPC board are received in a space between the two arcuate protrusion bars.

16. The display device according to claim 12, wherein the holding structure further comprises a main body, a through hole defined through the main body, and one or more fixing members configured to accommodate the one or more magnetic members; each fixing member comprises two substantially parallel first sidewalls, two substantially parallel second sidewalls, a resisting wall, and an elastic arm; the first sidewalls are arranged opposite to the second sidewalls, the resisting wall is arranged between the first sidewalls and the second sidewalls; the first sidewalls, the second sidewalls, and the resisting wall cooperatively form a receiving space having an opening to receive a magnetic member.

17. The display device according to claim 16, wherein the elastic arm comprises a connecting end and a free end, the connecting end is connected to the main body, the free end is adjacent to the opening, and the magnetic member is put into the receiving space through the opening.

18. The display device according to claim 17, wherein each of the one or more magnetic members is substantially cylindrical, and each fixing member further comprises an arcuate bottom wall formed at a bottom of the receiving space to conform to a shape of the magnetic member.
